(19) United States
(12) Patent Application Publication
(10) Pub. No.: US 2007/0166884 A1
(43) Pub. Date: Jul. 19, 2007

(54) Circuit board and package structure thereof

(75) Inventors: Hao Wei Li, Taichung (TW); Chien Chih Chen, Taichung (TW); Chung Pao Wang, Taichung (TW); Yung Chuan Ku, Taichung (TW); Yun Lung Tsai, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/497,593

(22) Filed: Aug. 1, 2006

(30) Foreign Application Priority Data
Dec. 29, 2005 (TW) 094147171

(51) Int. Cl. H01L 21/00

(52) U.S. Cl. 438/113

(57) ABSTRACT

A circuit board and a package structure thereof are proposed. The circuit board includes a main body and a solder mask layer covered on a surface of the main body. The circuit board is formed with a cutting path to define a plurality of array-arranged circuit board units, wherein the solder mask layer is formed with a groove at a position corresponding to the cutting path to expose the main body of the circuit board. By such arrangement, when a laser is employed to perform a singulation process after a chip mounting process and a packaging process have been completed on the circuit board unit, the problem wherein the solder mask layer melts on the cutting path of the circuit board due to a thermal effect caused by the laser is avoided, so as to avoid the generation of irregular and uneven surface of the cutting plane. Additionally, chippings on a surface of a substrate can be prevented from being generated, so as to avoid contamination of subsequent processes.

### FIELD OF THE INVENTION

The present invention relates to a circuit board and a package structure thereof, and more particularly, to a circuit board and a package structure thereof for packaging a chip.

### BACKGROUND OF THE INVENTION

Small-sized integrated circuit package units are usually formed on a single matrix substrate in a batch manner. Such a matrix substrate is predetermined with a plurality of packaging areas, and each of the packaging areas serves to form a package unit. After performing an encapsulating process, a singulation process is subsequently performed to divide the matrix substrate into individual package units. The package units formed by such a method include thin and fine ball grid array (TFBGA) packages and quad flat non-leaded (QFN) packages, etc. U.S. Pat. No. 5,776,798 and No. 6,281,047 have disclosed the foregoing techniques to form a plurality of semiconductor package units in a batch manner.

Referring to fabrication of a TFBGA package shown in FIG. 1A and FIG. 1B, a matrix substrate module plate 10 serving as a substrate is prepared with a plurality of substrate units 100, wherein a single TFBGA package unit is to be formed at a position corresponding to each of the substrate units 100. After performing processes including chip mounting, wire bonding, and package molding on each of the substrate units 100, a singulation process can be performed between each of the substrate units, so as to form a plurality of TFBGA package units.

FIG. 2A and FIG. 2B constitute an overall top-view diagram and detailed side-view diagram, respectively, showing fabrication of a memory card according to Taiwan Patent No. 217280. A semiconductor chip 21 and passive components 23 are mounted and electrically connected within each of a plurality of substrate units 200 formed on an array-arranged substrate module plate 20. Then, an encapsulant (not shown in the figure) is formed on the entire substrate module plate 20 prior to a singulation process being performed using a grinding wheel cutter along two or more edges of each of the substrate units 200. Thus, a plurality of rectangular packages 2 can be formed in a batch manner before being embedded into a case 26. Therefore, a substrate unit with reduced overall dimensions (compared to the total area that would be used if using multiple individual substrates) is used to form a plurality of packages in an efficient batch manner, so as to minimize both production and material costs.

In order to meet the increasing demand for light, thin, short and miniaturized electronic devices, memory card profiles need to be as small as possible. Therefore, existing designs have been redesigned to smaller formats. For example, the multi media card (MMC) specification has been reworked into the RSMMC and a MMC-micro formats, and the secure digital card (SD) has been redesigned as the mini-SD and the micro-SD formats. Along with the modification of the designs and fabrication processes, the shape of the memory card has changed from the foregoing prior-art rectangular shape consisting of linear lines to curve line (non-linear). However, in that the foregoing singulation process using a grinding wheel cutter can only form straight cutting paths, the processing requirements of a card-type package with a non-linear line shape cannot be met by the same singulation process. Moreover, the foregoing technique needs to additionally provide a lid for the package after packaging the chip. Hence, the additional requirement of the lid is cost-ineffective and the attachment of the case to the package further complicates the fabrication process, so as to reduce economy.

Accordingly, U.S. Patent No. 2004/0259291 has disclosed a technique to process a memory card package with a non-linear line shape without the use of a lid. Firstly, the processes of chip mounting and wire bonding are performed on each of a plurality of substrate units formed on a substrate module plate. Then, an encapsulating process is performed on the entire substrate module plate before performing a singulation process on the area to be formed with memory card packages using a water jet or a laser, such that a plurality of memory card packages with curve shapes can be formed.

Referring to the foregoing technique, regardless of whether fabricating a TFBGA or a memory card package, the substrate for carrying a chip is covered with a solder mask layer made of a high molecular material on a surface thereof. However, when the singulation process is performed between each of the substrate units using the laser, the solder mask layer can melt due to the thermal effect caused by the laser. Therefore, the generation of irregular and uneven surface of the cutting plane may result, and chippings may remain on the surface of the substrate, such that subsequent processes may be contaminated as a consequence.

### SUMMARY OF THE INVENTION

In light of the above prior-art drawbacks, a primary objective of the present invention is to provide a circuit board and a package structure thereof by which melting of the solder mask layer can be prevented while performing a singulation process using a laser.

Another objective of the present invention is to provide a circuit board and a package structure thereof by which the generation of irregular and uneven surface along a cutting path can be avoided.

Still another objective of the present invention is to provide a circuit board and a package structure thereof by which the generation of chippings on a surface of a substrate after a singulation process can be avoided.

A further objective of the present invention is to provide a circuit board and a package structure thereof by which contamination of subsequent processes to be performed after a singulation process can be prevented.

In accordance with the above and other objectives, the present invention proposes a circuit board and a package structure thereof. The circuit board can be array-arranged or singularly arranged. When arranged in arrays, the circuit board comprises a plurality of circuit board units. Also, the circuit board comprises a main body and a solder mask layer covering a surface of the main body. A cutting path is formed surrounding each of the circuit board units, and the solder mask layer is formed with a groove at a position corresponding to the cutting path to expose the main body of the circuit board.

The main body of the circuit board comprises at least an insulating core layer and at least a patterned circuit layer built on the insulating core layer. Further, the width of the groove is greater than the cutting width of the cutting path.

Referring to a single circuit board unit produced by performing a singulation process of the foregoing array-arranged circuit board, the circuit board unit comprises a main body and a solder mask layer covering a surface of the main body. The plane size of the solder mask layer is smaller than that of the main body of the circuit board unit, so as to expose one or more edges of the main body of the circuit board unit.

Moreover, the present invention also proposes a semiconductor package structure according to the foregoing circuit board structure. The semiconductor package structure comprises a circuit board that comprises a main body and a solder mask layer covering a surface of the main body and formed with a cutting path for defining a plurality of array-arranged circuit board units, wherein the solder mask layer is formed with a groove at a position corresponding to the cutting path to expose the main body; a semiconductor chip mounted and electrically connected to each of the circuit board units; and an encapsulant formed on the circuit board for encapsulating the semiconductor chip.

In another embodiment of the semiconductor package structure proposed in the present invention, a singulation process is performed along the cutting path between each of the circuit board units on the foregoing array-arranged semiconductor package structure, so as to form individual (one-chip, generally) semiconductor package structures. Such a semiconductor package structure comprises a circuit board unit, wherein a solder mask layer covers a surface of the circuit board unit, and the plane size of the solder mask layer is smaller than that of the main body of the circuit board unit, so as to expose one or more edges of the main body of the circuit board unit; a semiconductor chip mounted and electrically connected to the circuit board unit; and an encapsulant formed on the circuit board unit for encapsulating the semiconductor chip.

Accordingly, referring to the circuit board and the package structure thereof proposed in the present invention, the solder mask layer covering the surface of the array-arranged circuit board is formed with a groove at a position corresponding to the cutting path formed surrounding each of the circuit board units, such that the main body of the circuit board can be exposed. Therefore, when performing a singulation process using a cutting tool such as a laser, the problem of the solder mask layer melting on the cutting path of the circuit board due to the thermal effect caused by the laser is solved, so as to avoid the generation of irregular and uneven surface of a cutting plane. Additionally, generation of chippings on a surface of a substrate can be prevented, so as to avoid contamination of subsequent processes.

### BRIEF DESCRIPTION OF THE DRAWINGS

The present invention can be more fully understood by reading the following detailed description of the preferred embodiments, with reference made to the accompanying drawings, wherein:

FIG. 1A and FIG. 1B are top-view and side-view diagrams showing a prior-art thin and fine ball grid array (TFBGA) package;

FIG. 2A and FIG. 2B are, respectively, an overall top-view diagram of an array-arranged circuit board and a detailed cutaway side-view of an individual circuit board unit of the array-arranged circuit board shown in FIG. 2A depicting fabrication of a memory card according to Taiwan Patent No. 217280;

FIG. 3A is a bottom view of a circuit board according to the first preferred embodiment of the present invention;

FIG. 3B is a cross-sectional view of a circuit board according to the first preferred embodiment of the present invention;

FIG. 4A and FIG. 4B are, respectively, a cross-sectional view and a bottom view of a circuit board unit formed by performing a singulation process to the array-arranged circuit board shown in FIG. 3A and FIG. 3B;

FIG. 5 is a cross-sectional view of a semiconductor package structure according to the present invention;

FIG. 6 is a close-up view showing the package structure produced by performing a singulation process to the semiconductor package structure shown in FIG. 5 along a cutting path surrounding each circuit board unit;

FIG. 7 is a cross-sectional view of a circuit board according to the second preferred embodiment of the present invention; and

FIG. 8 is a bottom view of a circuit board according to the third preferred embodiment of the present invention.

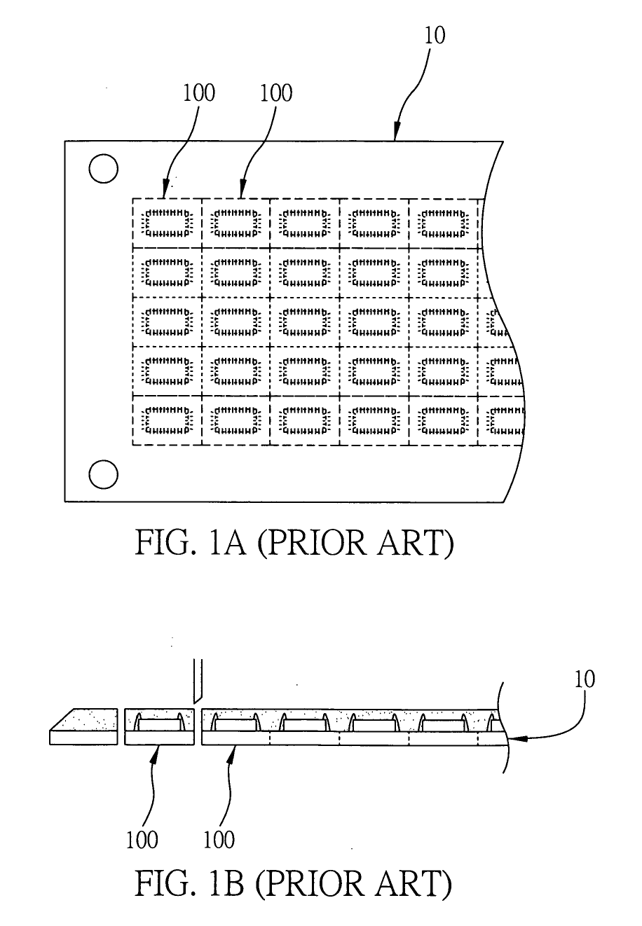

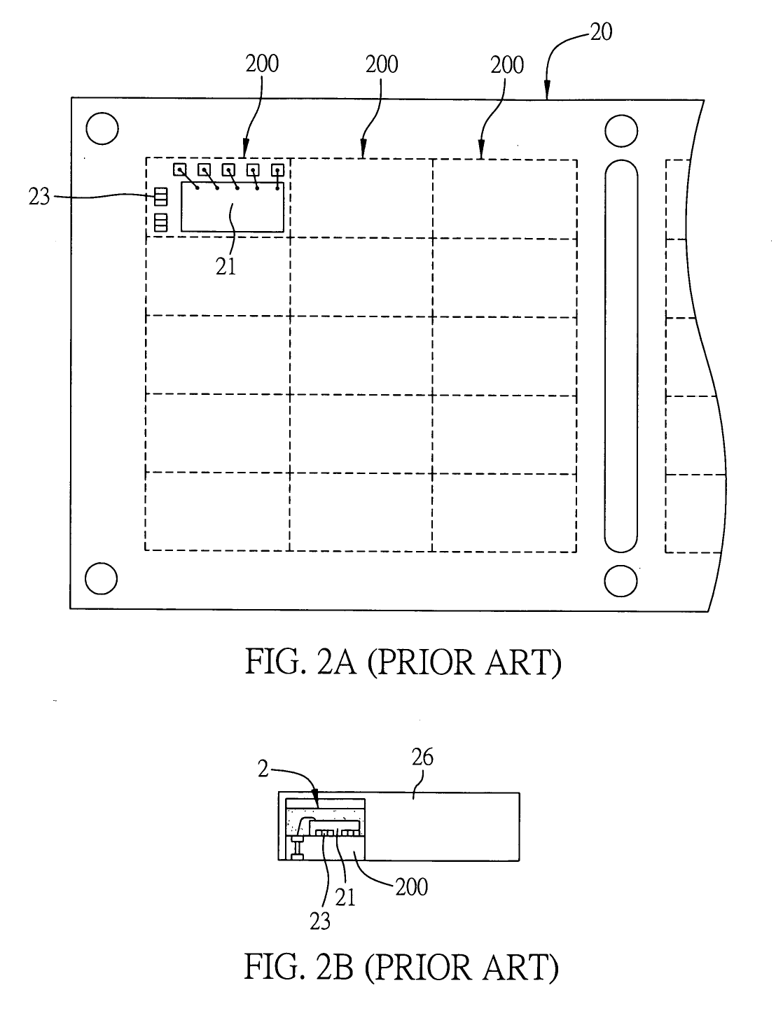

### DETAILED DESCRIPTION OF THE EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention. Note that these drawings are simplified schematic diagrams, and thus only structures relevant to the present invention are illustrated. Also, these structures are not drawn according to actual amounts, shapes and dimensions. The amounts, shapes and dimensions are design factors and the arrangement of the structures may be very complex in reality.

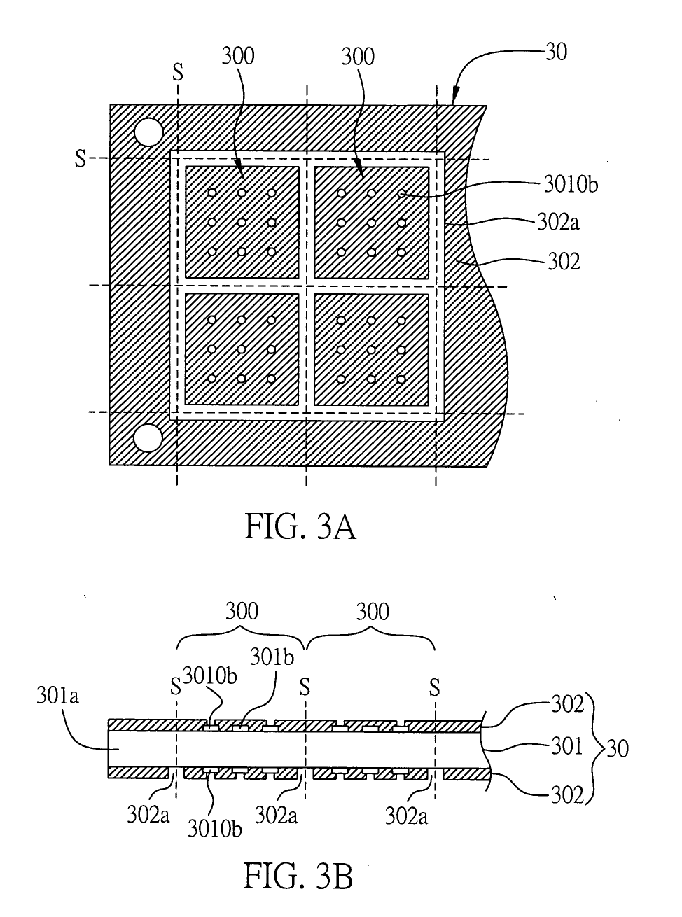

FIG. 3A and FIG. 3B are respectively a bottom view and a cross-sectional view of a circuit board according to the first preferred embodiment of the present invention.

Referring to FIG. 3A and FIG. 3B, an array-arranged circuit board 30 having a plurality of circuit board units 300 comprises a main body 301 and a solder mask layer 302 covering the top and bottom surfaces of the main body 301. A cutting path S is formed surrounding each of the circuit board units 300, and the solder mask layer 302 on the bottom side of the circuit board 30 is formed with a groove 302a to expose the main body 301 of the circuit board.

The circuit board 30 comprises a plurality of circuit board units 300. Processes including chip mounting, electrical connection formation between a chip and the circuit board unit, and package molding can be performed on each of the circuit board units. Subsequently, a singulation process can be performed between each of the circuit board units 300, so as to form a plurality of package units. The circuit board 30 can be but is not limited to a package substrate applied to a semiconductor package such as a ball grid array (BGA) package, especially a thin and fine ball grid array (TFBGA) package.

The main body 301 of the circuit board comprises at least an insulating core layer 301a and at least a patterned circuit layer 301b built on the insulating core layer 301a. The insulating layer 301a can be selected from the group consisting of bismaleimide triazine (BT), a mixture of an epoxy resin and a glass fiber (FR4), and the like. Additionally, the patterned circuit layer 301b is typically a copper metal layer.

The solder mask layer 302 covering the main body 301 serves to cover the patterned circuit layer 301b, so as to prevent the patterned circuit layer 301b from being contaminated or damaged by the outside environment. The solder mask layer 302 is a high molecular material such as an epoxy. Further, the solder mask layer 302 is formed with openings to expose one or more electrical pads 3010b such as bond finger or bond pads, etc. formed in the patterned circuit layer, wherein the electrical pad serves for external electrical connection.

As mentioned, a cutting path S is formed on the circuit board 30 such that it surrounds each of the circuit board units 300. Also, the solder mask layer 302 on the bottom side of the circuit board 30 is formed with a groove 302a at a position corresponding to the cutting path S to expose the insulating layer 301a of the main body 301 of the circuit board 30. In the present embodiment, the groove 302a is mainly formed on the board side of the circuit board 30 which can be subsequently electrically connected to an external device (such as a printed circuit board). Therefore, after performing a chip mounting process and a packaging process on a chip side of the circuit board, a singulation process can be performed along the groove 302a formed on the board side of the circuit board, provided that the width of the groove 302a is greater than width of the cutting path S.

Accordingly, when a tool, especially a laser tool, is used to subsequently perform a singulation process along the cutting path S surrounding each of the circuit board units 300, the main body 301 of the circuit board is directly cut and the solder mask layer 302 is prevented from contact. Thus, the problem of the solder mask layer 302 formed on the edge of the product melting due to the thermal effect caused by the laser is solved, the avoiding the generation of irregular and uneven surface of the cutting plane. Furthermore, generation of chippings on the surfaces of a substrate is prevented, so as to avoid contamination of subsequent processes.

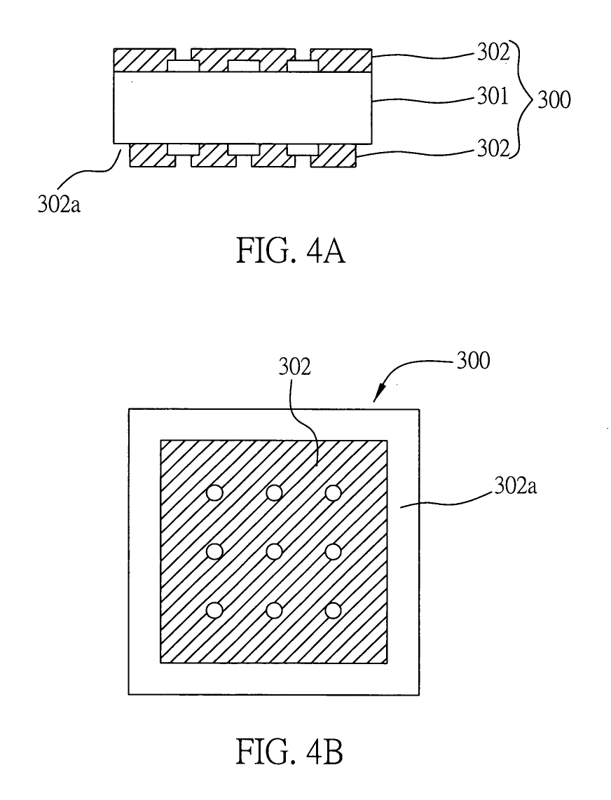

FIG. 4A and FIG. 4B are, respectively, a cross-sectional view and a bottom view of one of the plurality of circuit board units 300 formed by a singulation process that is applied to the foregoing array-arranged circuit board 30. The circuit board unit 300 comprises a main body 301 and a solder mask layer 302 covering a surface of the main body 301. The plane size of the solder mask layer 302 is smaller than that of the main body 301 of the circuit board unit, so as to expose an edge of the main body 301 of the circuit board unit.

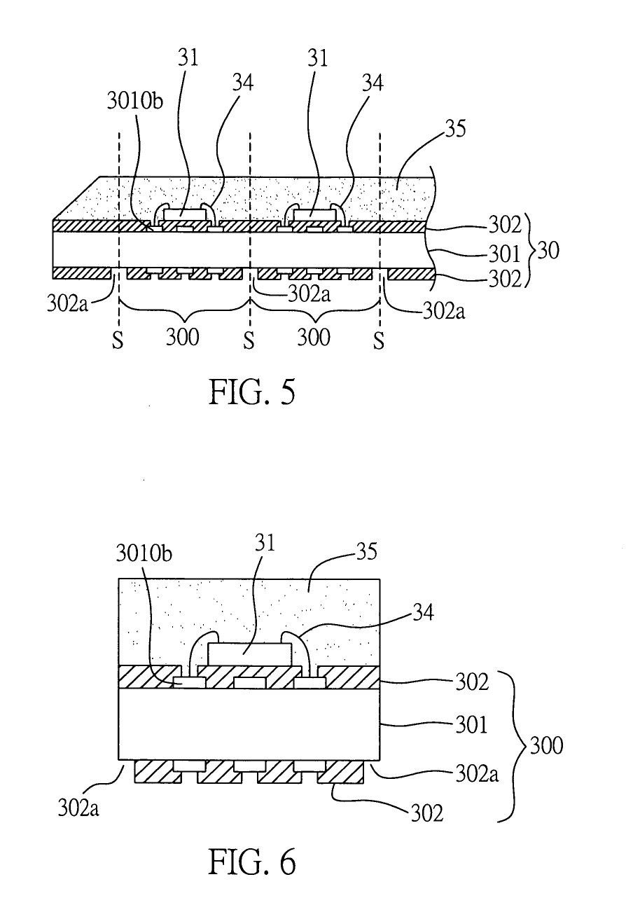

FIG. 5 is a cross-sectional view of a array-arranged semiconductor package structure formed by performing a chip packaging process to the circuit board shown in FIG. 3A and FIG. 3B. Referring to FIG. 5, the array-arranged semiconductor package structure comprises an array-arranged circuit board 30 that is formed with a plurality of circuit board units 300 and covered by a solder mask layer 302 on a surface thereof, wherein a cutting path S is formed surrounding each of the circuit board units 300, and the solder mask layer 302 is formed with a groove 302a at a position corresponding to the cutting path S to expose the main body 301 of the circuit board; a semiconductor chip 31 mounted and electrically connected to each of the circuit board units 300; and an encapsulant 35 formed on the circuit board 30 for encapsulating the semiconductor chip 31. The semiconductor chip 31 can be electrically connected to an electrical pad 3010b (such as a bond finger) exposed from the solder mask layer 302 on the circuit board unit 300 by gold wires 34. Meanwhile, the encapsulant 35 serves to encapsulate the semiconductor chip 31 and the gold wires 34 to prevent any damage or contamination from the outside environment. Moreover, apart from a wire bonding method, the semiconductor chip 31 can also be electrically connected to the circuit board unit 300 by a flip-chip method, and thus the electrical connection method in the present invention is not limited by the present embodiment.

FIG. 6 is a schematic diagram showing a package structure formed by performing a singulation process to the array-arranged package structure shown in FIG. 5 along the cutting path S surrounding each of the circuit board units 300, or a package structure formed by performing a chip mounting process and a packaging process on the circuit board unit 300 shown in FIG. 4A. Referring to FIG. 6, the package structure comprises a circuit board unit 300 which is formed with a solder mask layer 302 covering on a surface thereof, wherein the plane size of the solder mask layer 302 is smaller than that of a main body 301 of the circuit board unit, so as to expose an edge of the main body 301 of the circuit board unit; a semiconductor chip 31 mounted and electrically connected to the circuit board unit 300; and an encapsulant 35 formed on the circuit board unit 300 for encapsulating the semiconductor chip 31.

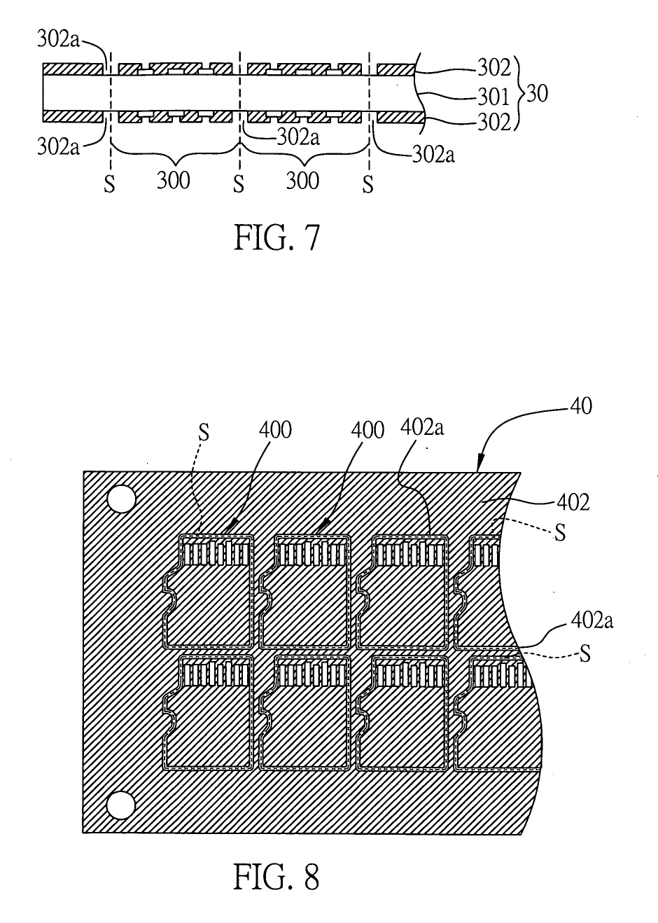

FIG. 7 is a cross-sectional view of a circuit board according to the second preferred embodiment of the present invention. The circuit board in the second preferred embodiment is similar to that in the first preferred embodiment, and only differs in that the solder mask layer 302 is formed with a groove 302a at a position corresponding to the cutting path S on the upper surface and the lower surface (the chip side and the board side) of the main body 301 of the circuit board, so as to expose the main body 301 of the circuit board. Therefore, when a laser is subsequently employed to perform a singulation process along the cutting path S formed surrounding each of the circuit board units 300, the solder mask layer 302 can be prevented from being contacted and melted, so as to avoid the generation of an irregular and uneven surface and chippings on the surface of the substrate.

FIG. 8 is a bottom view of a circuit board according to the third preferred embodiment of the present invention. The circuit board in the third preferred embodiment is similar to those in the first and second preferred embodiments, and only differs in that the circuit board can be applied to a card-type package structure.

Referring to FIG. 8, a circuit board 40 comprises a plurality of circuit board units 400 and is formed with a cutting path S (shown as the dashed line) at a position surrounding each of the circuit board units 400, such that a solder mask layer 402 formed on a surface of the circuit board 40 is formed with a groove 402a at a position corresponding to the cutting path S to expose a main body of the circuit board. Moreover, a cutting path S having a non-linear line shape can be formed surrounding each of the circuit board units 400, such that the cutting path S with the non-linear line shape is able to meet the design requirements of semiconductor packages with demanding shapes or appearance (such as the micro-SD card-type package). After performing processes including chip mounting and packaging, a laser tool can be used to subsequently perform a singulation process to the main body of the circuit board along the cutting path S, such that the solder mask layer 402 can be prevented from being contacted and melted. Therefore, prior-art drawbacks such as generation of irregular surface chippings and contamination of subsequent processes can be eliminated.

Accordingly, referring to the circuit board and the package structure thereof proposed in the present invention, the solder mask layer covering the surface of the array-arranged circuit board is formed with a groove at a position corresponding to the cutting path formed surrounding each of the circuit board units, such that the main body of the circuit board can be exposed. Therefore, when performing a singulation process using a tool such as a laser, the problem of the solder mask layer melting on the cutting path of the circuit board due to the thermal effect caused by the laser can be solved, so as to avoid the generation of irregular and uneven surface of a cutting plane. Additionally, generation of chippings on one or more surfaces of a substrate can be prevented, so as to avoid contamination of subsequent processes.

Further, apart from the ball grid array (BGA) package substrate, the circuit board proposed in the present invention can be also applied to card-type packages, other structures for carrying and packaging chips, or even general printed circuit boards.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A circuit board formed with a cutting path for defining a plurality of array-arranged circuit board units, comprising:
a main body; and
a solder mask layer covered on a surface of the main body, wherein the solder mask layer is formed with a groove at a position corresponding to the cutting path, so as to expose the main body.

2. The circuit board of claim 1, wherein the main body comprises at least an insulating core layer and at least a patterned circuit layer built on the insulating core layer.

3. The circuit board of claim 2, wherein the groove serves to expose the insulating core layer.

4. The circuit board of claim 1, wherein the width of the groove is greater than the cutting width of the cutting path.

5. The circuit board of claim 1, wherein the circuit board can be formed with a plurality of circuit board units after a singulation process is performed along the cutting path, the circuit board units comprising a main body and a solder mask layer covered on a surface of the main body, wherein the plane size of the solder mask layer is smaller than that of the main body of the circuit board unit, so as to expose an edge of the main body of the circuit board unit.

6. The circuit board of claim 1, wherein the circuit board can be a package substrate applied to a ball grid array (BGA) semiconductor package, a package substrate applied to a thin and fine ball grid array (TFBGA) package, or a circuit board applied to a card-type package.

7. The circuit board of claim 1, wherein the solder mask layer is formed with an opening to expose an electrical pad formed on the circuit board for external electrical connection.

8. The circuit board of claim 1, wherein the groove of the solder mask layer is formed on an upper surface and a lower surface of the main body.

9. The circuit board of claim 1, wherein the groove of the solder mask layer is formed on a single surface of the main body.

10. The circuit board of claim 1, wherein a laser is applied to perform a singulation process on the circuit board.

11. The circuit board of claim 1, wherein an non-linear cutting path is formed on the circuit board.

12. A semiconductor package structure, comprising of:
a circuit board comprising a main body and a solder mask layer covered on a surface of the main body, the circuit board being formed with a cutting path for defining a plurality of array-arranged circuit board units, wherein the solder mask layer is formed with a groove at a position corresponding to the cutting path to expose the main body;
a semiconductor chip mounted and electrically connected to each of the circuit board units; and
an encapsulant formed on the circuit board for encapsulating the semiconductor chip.

13. The semiconductor package structure of claim 12, wherein the main body comprises at least an insulating core layer and at least a patterned circuit layer built on the insulating core layer.

14. The semiconductor package structure of claim 13, wherein the groove serves to expose the insulating core layer.

15. The semiconductor package structure of claim 12, wherein the width of the groove is greater than the cutting width of the cutting path.

16. The semiconductor package structure of claim 12, wherein the package structure can be formed with a plurality of package units by performing a singulation process along the cutting path, the package units comprising:
a circuit board unit comprising a main body and a solder mask layer covered on a surface of the main body, wherein the plane size of the solder mask layer is smaller than that of the main body of the circuit board unit, so as to expose an edge of the main body of the circuit board unit;
a semiconductor chip mounted and electrically connected to the circuit board unit; and
an encapsulant formed on the circuit board unit for encapsulating the semiconductor chip.

17. The semiconductor package structure of claim 12, wherein the circuit board can be a package substrate applied to a ball grid array (BGA) semiconductor package, a package substrate applied to a thin and fine ball grid array (TFBGA) package, or a circuit board applied to a card-type package.

18. The semiconductor package structure of claim 12, wherein the solder mask layer is formed with an opening to expose an electrical pad formed on the circuit board for external electrical connection.

19. The semiconductor package structure of claim 12, wherein the groove of the solder mask layer is formed on an upper surface and a lower surface of the main body.

20. The semiconductor package structure of claim 12, wherein the groove of the solder mask layer is formed on a single surface of the main body.

21. The semiconductor package structure of claim 12, wherein a laser is employed to perform a singulation process on the circuit board.

22. The semiconductor package structure of claim 12, wherein an non-linear cutting path is formed on the circuit board.
